(19) United States
(12) Patent Application Publication
(10) Pub. No.: US 2013/0155126 A1
(43) Pub. Date: Jun. 20, 2013

(54) DETERMINATION OF DISPLAY DEVICE POWER CONSUMPTION

(71) Applicants: Frederick L. Lathrop, Spring, TX (US); John Frederick, Spring, TX (US); Thong Thai, Houston, TX (US)

(72) Inventors: Frederick L. Lathrop, Spring, TX (US); John Frederick, Spring, TX (US); Thong Thai, Houston, TX (US)

(21) Appl. No.: 13/819,325

(22) PCT Filed: Aug. 31, 2010
(86) PCT No.: PCT/US10/47351

§ 371 Date: Feb. 26, 2013

(51) Int. Cl. G01R 21/00; G09G 5/00; G09G 5/10; G06F 17/00

(52) U.S. Cl. CPC G01R 21/00; G06F 17/00; G09G 5/001; G09G 5/10
USPC 345/690; 702/62; 345/211

(57) ABSTRACT

Example embodiments disclosed herein relate to determination of display device power consumption. In example embodiments, an operating parameter of a display device of a computing device is received, which, in some embodiments, may be a current level of brightness of the display device. A level of power consumption of the display device may then be determined based on the operating parameter.

### BACKGROUND

Consumers may desire to manage power consumption of a computing device to reduce electricity costs, extend battery life when running the device on battery power, and minimize the carbon footprint of the device. Power consumption of the components of a computing device is therefore of significant importance to many consumers when selecting a computing device and evaluating satisfaction with the device. This is especially true for the power consumption of integrated and external display devices of the computing device, since displays account for a considerable proportion of the total power consumption of the device.

### BRIEF DESCRIPTION OF THE DRAWINGS

The following detailed description references the drawings, wherein:

FIG. 1 is a block diagram of an example computing device including instructions for determining a respective level of power consumption of each display device available to the computing device;

FIG. 2 is a block diagram of an example computing device in communication with an external display device, the computing device including a plurality of modules for determining a level of power consumption of the external display device;

FIG. 3 is a flowchart of an example method for determining a level of power consumption and coordinating a brightness setting of each of a plurality of display devices;

FIG. 4 is a flowchart of an example method for determining and displaying a level of power consumption of a plurality of display devices of a computing device based on a brightness setting of each display;

FIG. 5 is a flowchart of an example method for coordinating brightness settings of a plurality of display devices of a computing device;

FIG. 6 is a flowchart of an example method for controlling power states of a plurality of display devices of a computing device;

FIG. 7A is a block diagram of an example user interface for displaying a level of power consumption and controlling a power state of a plurality of display devices of a computing device; and

FIG. 7B is a block diagram of an example user interface for coordinating brightness settings of a plurality of display devices of a computing device.

### DETAILED DESCRIPTION

As detailed above, the power consumption of a computing device and its displays may be of significant interest to the end user. To this end, embodiments disclosed herein relate to determination of power consumption of one or more display devices of a computing device, which may include an external display device. In some embodiments, a computing device may receive a current operating parameter of an external display device. The computing device may then receive power consumption data describing a level of power consumption of the external display device based on the operating parameter. Finally, the computing device may determine a level of power consumption of the external display based on application of the current operating parameter to the power consumption data.

In some embodiments, the computing device may also enable coordination of power consumption and/or power states of one or more external display devices. For example, a computing device may receive a specified brightness level from a user and, in response, transmit a brightness coordination message to each external display device instructing each display to set its brightness level to the user-specified level. As another example, a computing device may receive an enable indication for an external display device and, in response, instruct the external display device to enter a power on, power off, or sleep state.

In this manner, example embodiments disclosed herein provide the user with detailed information regarding the power consumption of each display of a computing device. In addition, example embodiments allow a user to actively manage power consumption of the display devices by coordinating a brightness level of the displays and controlling the power state of each display device. Additional embodiments and applications of such embodiments will be apparent to those of skill in the art upon reading and understanding the following description.

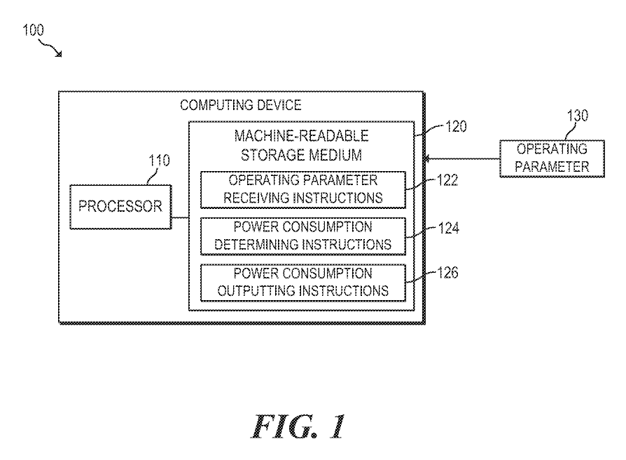

Referring now to the drawings, FIG. 1 is a block diagram of an example computing device 100 including instructions 122, 124, 126 for determining a respective level of power consumption of each display device available to the computing device 100. Computing device 100 may be, for example, a notebook computer, a desktop computer, an all-in-one system, a slate computing device, a portable reading device, a wireless email device, a mobile phone, or any other computing device including one or more integrated display devices and/or coupled to one or more external display devices. In the embodiment of FIG. 1, computing device 100 includes processor 110 and machine-readable storage medium 120.

Processor 110 may be one or more central processing units (CPUs), semiconductor-based microprocessors, and/or other hardware devices suitable for retrieval and execution of instructions stored in machine-readable storage medium 120. Processor 110 may fetch, decode, and execute instructions 122, 124, 126 to implement the power determination procedure described in detail below. As an alternative or in addition to retrieving and executing instructions, processor 110 may include one or more integrated circuits (ICs) or other electronic circuits that include a number of electronic components for performing the functionality of one or more of instructions 122, 124, 126.

Machine-readable storage medium 120 may be any electronic, magnetic, optical, or other physical storage device that contains or stores executable instructions. Thus, machine-readable storage medium may be, for example, Random Access Memory (RAM), an Electrically Erasable Programmable Read-Only Memory (EEPROM), a storage drive, a Compact Disc Read Only Memory (CD-ROM), and the like. As described in detail below, machine-readable storage medium 120 may be encoded with a series of executable instructions for determining a level of power consumption of each display device available to computing device 100.

Machine-readable storage medium 120 may include operating parameter receiving instructions 122, which may receive a respective operating parameter 130 for each of a plurality of display devices. These display devices may include an integrated display device, such as a Liquid Crystal Display (LCD) panel or other type of display panel. The display devices may also include one or more external display devices, such as an LCD panel, a plasma panel, a Cathode Ray Tube (CRT) display, or any other display device.

The operating parameter 130 received by instructions 122 may describe any characteristic or characteristics of the display device that impact the power consumption of the display. For example, the operating parameter 130 may be a set of one or more on-screen display (OSD) settings of the display device. In such embodiments, the OSD settings may include a current brightness or luminance setting of the display, expressed as a brightness setting (e.g., an integer between 0 and 100) or as a measured level of brightness (e.g., a measure of light intensity in candelas per square meter or nits). In addition or as an alternative, the operating parameter 130 may include a current power state of the display (e.g., powered on, powered off, in a sleep state, etc.).

In some embodiments, receiving instructions 122 may receive the operating parameter 130 directly from the display device over a Display Data Channel (DDC), an Enhanced Display Data Channel (E-DDC), a Universal Serial Bus (USB) interface, or any other interface between computing device 100 and the display. Receiving instructions 122 may periodically poll each display device for the operating parameter 130 using the interface, such that instructions 122 retrieve an updated operating parameter 130 on a regular basis. Alternatively, receiving instructions 122 may receive an interrupt from the display device when the user changes the OSD setting of an operating parameter 130 that affects the power consumption. In such embodiments, receiving instructions 122 may poll the display device for an updated operating parameter 130 upon receipt of the interrupt.

As an alternative to receiving the operating parameter 130 from the display device, receiving instructions 122 may instead receive entry of the operating parameter 130 from the user of computing device 100. Additional techniques for obtaining the operating parameter 130 from the display device will be apparent to those of skill in the art.

Machine-readable storage medium 120 may also include power consumption determining instructions 124, which may determine a respective level of power consumption of each display device using the respective operating parameter 130 for each device. For example, determining instructions 124 may utilize the operating parameter to determine an estimated power consumption of each display as a number of Watts.

In some embodiments, determining instructions 124 may include instructions for receiving power consumption data describing a predetermined level of power consumption of each display device for each of a plurality of operating parameter settings. For example, the power consumption data may include a plurality of data points, each point representing the level of power consumption of the display device at a corresponding setting for the operating parameter. As a specific example, when the operating parameter 130 includes a brightness setting, the power consumption data may include a level of power consumption for each of a plurality of brightness settings (e.g., Watts at 0% brightness, 50% brightness, 90% brightness, and 100% brightness). In addition, the power consumption data may include data for various power states, such as the level of power consumption when the display is in the sleep mode and/or power off mode.

For example, in some embodiments, the power consumption data may be stored in the display device or another storage location according to the format specified in the following table:

TABLE 1
Example Format of Power Consumption Data

| | Byte(s) | | | | | |
|---|---|---|---|---|---|---|
| | 0 | 1-2 | 3-4 | 5-6 | 7-8 | 9-A |
| Data | Number of | Sleep | Watts at | Watts at | Watts at | Watts at |
| | entries | mode | 0% | 50% | 90% | 100% |
| | | | Brightness | Brightness | Brightness | Brightness |

In such embodiments, determining instructions 124 may retrieve each table entry by traversing the table using a power consumption table pointer. For example, determining instructions 124 may initially set the power consumption pointer to read the data from byte 0 using a command with an opcode of 0xEF. After setting the pointer, determining instructions 124 may read the table entry from the current position of the pointer using a command with the opcode 0xF0 and, in response, receive a value indicating the total number of entries in the table (five in this case). By repeating this process for each of the five power consumption entries, determining instructions 124 may retrieve the power consumption data for the display, which, as described below, may be used to determine the power consumption at any brightness level and when the display is in sleep mode.

As with receiving instructions 122, determining instructions 124 may use a variety of methods for receiving the power consumption data of the display device. In embodiments in which the power consumption data is stored in the display (e.g., in the Extended Display Identification Data (EDID)), determining instructions 124 may receive the power consumption data directly from the display device over a Display Data Channel (DDC), an Enhanced Display Data Channel (E-DDC), a Universal Serial Bus (USB) interface, or any other interface between computing device 100 and the display. Alternatively, determining instructions 124 may retrieve the power consumption data from a local or remote storage device accessible to computing device 100. As another alternative, a user may directly enter the power consumption data into a user interface displayed by computing device 100.

In embodiments in which determining instructions 124 receive power consumption data, instructions 124 may further include instructions for determining the level of power consumption of each display device based on application of the operating parameter to the received power consumption data. For example, determining instructions 124 may read the power consumption data to determine whether an exact match for the current operating parameter 130 is present in the power consumption data. If so, determining instructions 124 may directly read the corresponding level of power consumption. Otherwise, determining instructions 124 may use any of a variety of techniques to estimate the current level of power consumption corresponding to the current operating parameter 130. For example, determining instructions may use linear interpolation, polynomial interpolation, or another form of interpolation to estimate the current power consumption using the data points. An example method that utilizes interpolation to calculate a current level of power consumption is described below in connection with FIG. 4.

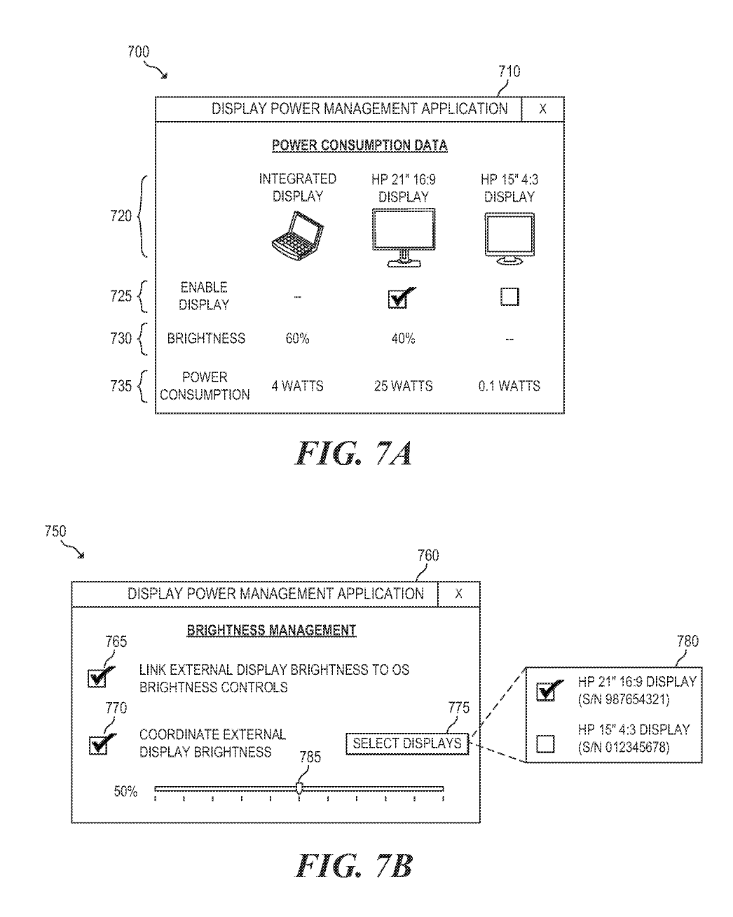

After the level of power consumption is determined for each display device, power consumption outputting instructions 126 may output each determined level of power consumption for each display device. For example, outputting instructions 126 may display a table or other data arrangement that identifies each display device, outputs the current operating parameter 130 used to determine the power consumption, and outputs the determined level of power consumption. An example user interlace for display of the level of power consumption of each display device is described below in connection with FIG. 7A.

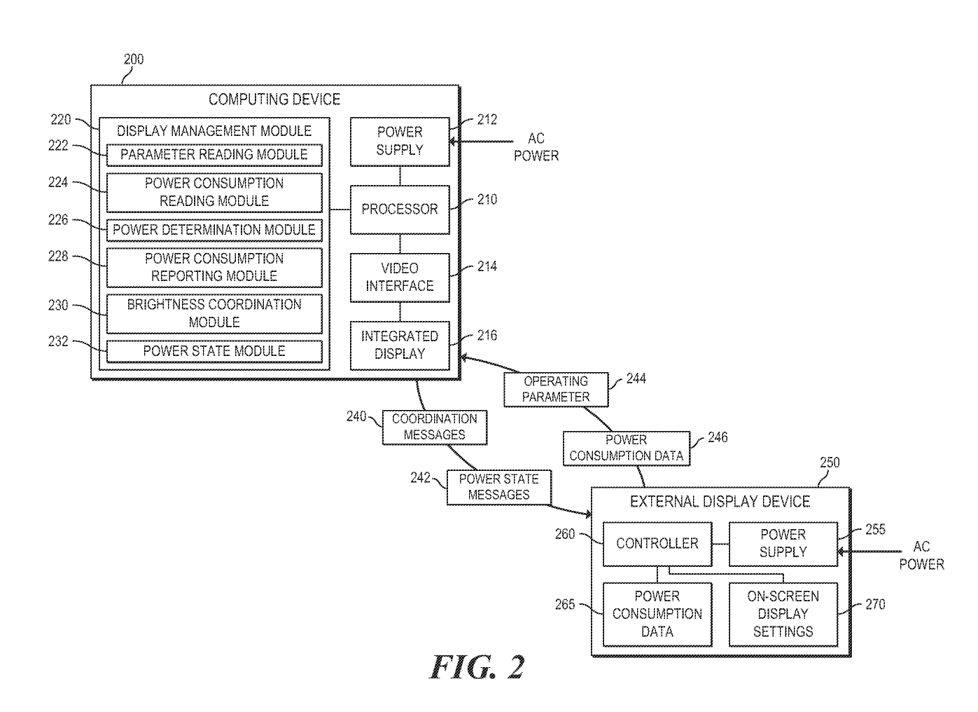

FIG. 2 is a block diagram of an example computing device 200 in communication with an external display device 250, the computing device 200 including a plurality of modules 220-232 for determining a level of power consumption of the external display device 250. As detailed below, computing device 200 may receive operating parameter 244 and power consumption data 246 from external display device 250 and use this data to determine a level of power consumption of external display device 250. Computing device 200 may also utilize coordination messages 240 to coordinate a brightness setting and power state messages 242 to control a power state of each external display device 250.

As with computing device 100 of FIG. 1, computing device 200 may be a notebook computer, a desktop computer, an all-in-one system, a slate computing portable reading device, a wireless email device, a mobile phone, or any other computing device. When computing device 200 is an all-in-one or notebook system, device 200 may include an integrated display 216 in addition to one or more external display devices 250. It should be noted, however, that computing device 200 may be a system that does not include an integrated display, such as a desktop computer. As with processor 110, processor 210 may be a CPU or microprocessor suitable for retrieval and execution of instructions and/or one or more electronic circuits configured to perform the functionality of one or more of the modules 220-232 described below.

Power supply 212 may be a hardware component that includes circuitry for distributing power to each component of computing device 200. For example, power supply 212 may receive electricity from an Alternating Current (AC) power source and convert this incoming power to Direct Current (DC) power usable by the components of computing device 200. Power supply 212 may therefore account for a portion of the power consumed by computing device 200 during its operation, while power supply 255 of external display device 250 may account for an additional portion of the power consumption.

Video interface 214 may be a hardware component in communication with integrated display 216 and one or more external display devices 250. Video interface 214 may be, for example, an integrated graphics chipset, a standalone graphics card, or any other hardware component suitable for exchange of data and control messaging with integrated display 216 and/or external display device 250. In operation, video interface 214 may transmit coordination messages 240 and power state messages 242, while receiving operating parameter 244 and power consumption data 246.

Integrated display 216 may be a display screen integrated into computing device 200, such as a Liquid Crystal Display (LCD) panel or a display panel implemented using another display technology. As described below, in some embodiments, display management module 220 may determine a level of power consumption and/or control a level of brightness of integrated display 216.

As detailed below, computing device 200 may include a series of modules 220-232 for managing power consumption of integrated display 216 and/or external display device 250. Each of the modules may include one or more hardware devices including electronic circuitry for implementing the functionality described below. In addition or as an alternative, each module may be implemented as a series of instructions encoded on a machine-readable storage medium of computing device 200 and executable by processor 210. It should be noted that in some embodiments, some modules are implemented as hardware devices, while other modules are implemented as executable instructions.

Display management module 220 may include a number of sub-modules 222-232 for managing power consumption of integrated display 216 and/or external display device 250. Display management module 220 may be, for example, a portion of a power management application that manages power consumption of a number of hardware components of computing device 200. Alternatively, display management module 220 may be a portion of a dedicated application for managing power consumption of integrated display 216 and/or external display device 250.

Parameter reading module 222 may be in communication with display devices 216, 250 for receiving a current operating parameter 244 of each display 216, 250. Parameter reading module 222 may receive the current operating parameter 244 from integrated display 216 and/or external display device 250 via video interface 214. For example, parameter reading module 222 may receive the operating parameter 244 via communication with external display 250 using a DDC, E-DDC, or USB communication interface. Alternatively, parameter reading module 222 may receive the current operating parameter 244 from a user of computing device 200 via, for example, a user interface displayed by display management module 220.

As described above in connection with instructions 122 of FIG. 1, the operating parameter 244 received by parameter reading module 222 may describe any characteristic or characteristics of display 216 and/or display 250 that impact the power consumption. For example, operating parameter 244 may be one or more on-screen display settings, such as a brightness setting. In addition or as an alternative, operating parameter 244 may include a current power state of the display 216, 250 (e.g., powered on, powered off, in sleep mode, etc.). Additional details for one implementation of parameter reading module 222 are provided above in connection with operating parameter receiving instructions 122 of FIG. 1.

Power consumption reading module 224 may receive power consumption data 246 describing a level of power consumption of integrated display 216 and/or external display 250 based on operating parameter 244. Power consumption reading module 224 may, for example, receive power consumption data 246 from integrated display 216 and/or external display device 250 via video interface 214. Alternatively, power consumption reading module 224 may retrieve power consumption data 246 from a storage location accessible to computing device 200, such as a local or remote storage drive.

As described above in connection with instructions 124 of FIG. 1, power consumption data 246 may describe a predetermined level of power consumption for the display device 216, 250 for each of a plurality of operating parameter settings. For example, power consumption data 246 may be a table including a plurality of data points describing a predetermined level of power consumption of display 216, 250 at each of a plurality of brightness settings and when the display 216, 250 is in sleep mode and/or power off mode. Additional details for one implementation of power consumption reading module 224 are provided above in connection with power consumption determining instructions 124 of FIG. 1.

Power determination module 226 may determine a level of power consumption of displays 216, 250 based on application of the current operating parameter 244 to the power consumption data 246. For example, when the exact operating parameter 244 (e.g., a particular brightness setting) is an entry in power consumption data 246, power determination module 226 may determine the level of power consumption based on a lookup.

Alternatively, when the exact operating parameter 244 does not appear in power consumption data 246, power determination module 226 may utilize an interpolation technique to derive the level of power consumption. For example, using the data points present in power consumption data 246, power determination module 226 may determine a line of best fit, a polynomial of best fit, or another mathematical function that best represents the plurality of data points or a subset of data points in data 246. Power determination module 226 may then utilize the derived function to interpolate the level of power consumption at the value specified by operating parameter 244.

Power consumption reporting module 228 may output the level of power consumption for each display 216, 250 as determined by power determination module 226. For example, reporting module 228 may output a table or other arrangement of data that includes the operating parameter 244 and a corresponding level of power consumption for each display 216, 250. As a specific example, when operating parameter 244 is a brightness setting, reporting module 228 may output the brightness setting of display 216 and/or display 250 and also output the corresponding level of power consumption for each display 216, 250. An example user interface displayed by reporting module 228 is described below in connection with FIG. 7A.

Brightness coordination module 230 may allow a user to coordinate brightness between each of the displays 216, 250 included in or coupled to computing device 200. Brightness coordination module 230 may first determine a brightness level specified by a user. For example, brightness coordination module 230 may receive a brightness level provided by a user using an operating system (OS) brightness control. Alternatively, brightness coordination module 230 may receive the brightness level in a user interface of display management module 220, such as the example user interface described below in connection with FIG. 7B. As yet another example, brightness coordination module 230 may utilize a brightness value specified by a user using an on-screen display (OSD) menu of external display 250 and received with operating parameter 244.

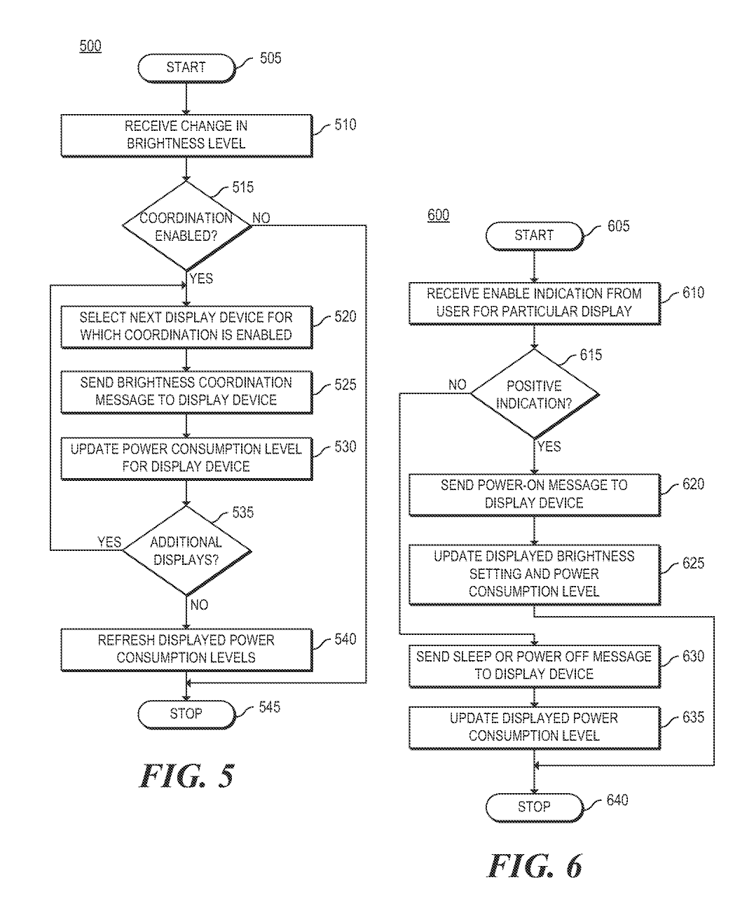

Regardless of the particular implementation, upon receipt of a modified brightness level from the user, brightness coordination module 230 may transmit a brightness coordination message 240 to each external display device 250. This message 240 may, for example, instruct the external display 250 to set its brightness setting to the setting included with the message 240 (e.g., a brightness level between 0 and 100). Alternatively, if supported by external display 250, the message 240 may instead instruct display 250 to set its brightness setting to a level of luminance corresponding to the brightness level specified by the user (e.g., 300 nits, 350 nits, etc.). In addition, when computing device 200 includes an integrated display 216, brightness coordination module 230 may also set the brightness setting of integrated display 216 to the user-specified value. In this manner, the user may simultaneously adjust the brightness of each display 216, 250 to a comfortable level, while also controlling a level of power consumption of each display 216, 250. Additional details for an example brightness coordination procedure are provided below in connection with FIG. 5.

Power state module 232 may allow a user to manage a power state of each external display 250 available to computing device 200. Power state module 232 may, for example, receive an enable indication from a user specifying whether a particular external display 250 is to be enabled or disabled. For example, the user may select a checkbox or similar interface element to specify whether to enable or disable a particular external display 250. An example user interface including elements 725 for selectively toggling a power state of each display is described below in connection with FIG. 7A.

Based on receipt of an enable indication from a user, power state module 232 may transmit a power state control message 242 to the external display device 250. For example, when the enable indication from the user is positive (e.g., activation of a checkbox or other element), power state module 232 may transmit a message 242 instructing the external display device 250 to enter a power on state. Alternatively, when the enable indication from the user is negative (e.g., deactivation of a checkbox or other element), power state module 232 may transmit a message 242 instructing the external display device 250 to enter a power off or sleep state. In this manner, the user may control the state and power consumption of each external display 250 using a single interface. Additional details for an example power state control procedure are provided below in connection with FIG. 6.

External display device 250 may be, for example, an LCD panel, a plasma panel, a Cathode Ray Tube (CRT) display, or any other display device. As with power supply 212, power supply 255 may be a hardware component for distributing power to the components of display 250.

Controller 260 may include circuitry that executes logic for managing display device 250. For example, controller 260 may be a semiconductor-based microprocessor, a microcontroller, or any other hardware device suitable for processing coordination messages 240 and power state messages 242 and transmitting operating parameters 244 and power consumption data 246.

As detailed above, in some embodiments, power consumption data 265 may be stored in external display device 250. In such embodiments, external display device 250 may maintain power consumption data 265 in the Extended Display Identification Data (EDID) of device 250. Alternatively, external display device 250 may store power consumption data 265 in a separate machine-readable storage medium, such as a non-volatile Random Access Memory (RAM) or a flash Read-Only Memory (ROM). In operation, controller 260 may transmit power consumption data 265 for use by computing device 200 in calculating a level of power consumption of display 250.

On-screen display (OSD) settings 270 may include a number of user-customizable settings of external display device 250. For example, OSD settings 270 may allow a user to customize a brightness setting, contrast setting, color levels, refresh rate, and other parameters that control the image outputted by display device 250. External display device 250 may store OSD settings 270 in any machine-readable storage medium, such as a non-volatile RAM or flash ROM. In operation, controller 260 may transmit one or more of the OSD settings 270 as an operating parameter 244 for use by computing device 200 in calculating a level of power consumption of display 250.

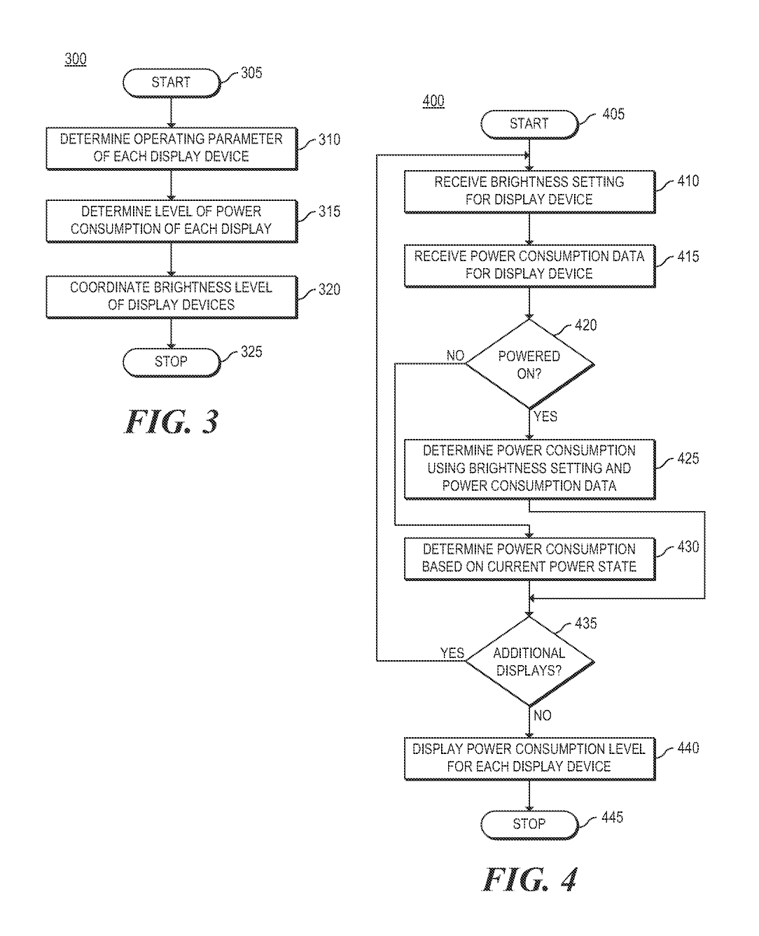

FIG. 3 is a flowchart of an example method 300 for determining a level of power consumption and coordinating a brightness setting of each of a plurality of display devices. Although execution of method 300 is described below with reference to computing device 100, other suitable components for execution of method 300 will be apparent to those of skill in the art (e.g., computing device 200). Method 300 may be implemented in the form of executable instructions stored on a machine-readable storage medium, such as storage medium 120, and/or in the form of electronic circuitry.

Method 300 may start in block 305 and proceed to block 310, where computing device 100 may determine one or more operating parameters 130 for each integrated or external display device available to computing device 100. Computing device 100 may receive the parameter 130 directly from each display device or receive the parameter 130 from the user. Each parameter 130 may describe one or more characteristics of the display device that impact the device's power consumption, such as a brightness setting and/or current power state of the display.

Upon receipt of the parameter 130 for each display, method 300 may proceed to block 315, where computing device 100 may determine a level of power consumption of each display based on the received operating parameter 130. In some embodiments, computing device 100 may access power consumption data that describes an amount of power consumed by the display at each of a plurality of settings of the operating parameter. Upon receipt of the power consumption data, computing device 100 may determine the level of power consumption based on a lookup in power consumption data. Alternatively, computing device 100 may use an interpolation technique to determine the level of power consumption when the exact operating parameter 130 for a particular display is not present in the power consumption data. In some embodiments, after determining the level of power consumption for each display, computing device 100 may output the determined level of power consumption of each display.

After computing device 100 determines the power consumption of each display, method 300 may proceed to block 320, where computing device 100 may coordinate a level of brightness of each of the display devices based on a user-specified brightness setting. For example, computing device 100 may receive the brightness setting from the user via an operating system brightness control, a user interlace element in a power management application, or via an on-screen display of an external display device.

Upon receipt of the brightness setting from the user, computing device 100 may transmit a brightness coordination message to each external display instructing each display to set its brightness level to the user-specified setting. Computing device 100 may also set the brightness level of an integrated display, if present, to the user-specified setting. Finally, method 300 may proceed to block 325, where method 300 may stop.

FIG. 4 is a flowchart of an example method 400 for determining and displaying a level of power consumption of a plurality of display devices 216, 250 of a computing device 200 based on a brightness setting of each display 216, 250. Although execution of method 400 is described below with reference to computing device 200 and, more specifically, modules 222-228, other suitable components for execution of method 400 will be apparent to those of skill in the art. Method 400 may be implemented in the form of executable instructions stored on a machine-readable storage medium and/or in the form of electronic circuitry.

Method 400 may start in block 405 and proceed to block 410, where parameter reading module 222 of computing device 200 may receive, from a particular display, an operating parameter 244 specifying a current brightness setting for the display. This brightness setting may be expressed, for example, as a percentage or level of brightness (e.g., a value between 0 and 100) or as a luminance level in nits.

Method 400 may then proceed to block 415, where power consumption reading module 226 may receive power consumption data 246 for the particular display device. This power consumption data 246 may include a number of measured levels of power consumption for each of a plurality of brightness settings of the display. The power consumption data 246 may also include a level of power consumption of the display when it is in a power off or sleep state.

Upon receipt of the power consumption data 246, method 400 may proceed to block 420, where power determination module 226 may determine whether the display device is currently powered on. When the display is an external display device 250, power determination module 226 may determine this by, for example, sending a message to display 250 requesting the current power state of the display 250. If the display is an integrated display 216, power determination module 226 may determine the state of integrated display 216 based, for example, on a query to video interface 214 or another component of computing device 200.

When power determination module 226 determines in block 420 that the display is currently powered on, method 400 may proceed to block 425. In block 425, power determination module 226 may determine the level of power consumption of the display using the current brightness setting and the power consumption data. For example, when the current brightness setting is included as an entry in the power consumption data, power determination module 226 may simply look up the corresponding level of power consumption.

Alternatively, when the current brightness setting is not included in the power consumption data, power determination module 226 may utilize an interpolation technique to derive the level of power consumption. For example, to utilize a linear interpolation technique, power determination module 226 may first select two data points, each including a brightness setting and a corresponding level of power consumption. Power determination module 226 may then determine the slope and y-intercept of the line that intersects the two points and determine the y-value of the line at the current brightness setting. Power determination module 226 may similarly utilize a polynomial interpolation technique by selecting n data points and identifying the polynomial of degree n−1 that intersects each of the points. As another example of an interpolation technique, power determination module 226 may determine a line, polynomial, or other function of best fit for a larger number of data points and determine the value of the function at the current brightness setting. After determination of the current level of power consumption, method 400 may proceed to block 435, described in detail below.

Alternatively, when power determination module 226 determines in block 420 that the display is not currently powered on, method 400 may proceed to block 430. In block 430, power determination module 226 may access the power consumption data to determine the level of power consumption of the display in its current power state (e.g., sleep mode or powered off). Method 400 may then proceed to block 435.

In block 435, power determination module 226 may determine whether there are additional display devices for which the level of power consumption is to be determined. If so, method 400 may return to block 410, where modules 222, 224, 226 may repeat the procedure for determining the level of power consumption of the next display. Otherwise, method 400 may proceed to block 440, where power consumption reporting module 228 may display the determined level of power consumption for each display using, for example, user interface 700 of FIG. 7A, described in detail below. Method 400 may then proceed to block 445, where method 400 may stop.

FIG. 5 is a flowchart of an example method 500 for coordinating brightness settings of a plurality of display devices of a computing device 200. Although execution of method 500 is described below with reference to computing device 200 and, more specifically, brightness coordination module 230, other suitable components for execution of method 500 will be apparent to those of skill in the art. Method 500 may be implemented in the form of executable instructions stored on a machine-readable storage medium and/or in the form of electronic circuitry.

Method 500 may start in block 505 and proceed to block 510, where brightness coordination module 230 may receive notification of a change in the brightness level by the user. For example, brightness coordination module 230 may receive notification of a change of an operating system brightness setting, an on-screen display setting of a display, or a brightness setting in a user interface of a power management application.

In block 515, brightness coordination module 230 may determine whether a brightness coordination setting is enabled. The user may control this setting using, for example, a selectable checkbox or other element in a user interface, such as element 770 of user interface 750 of FIG. 7B. In some embodiments, the user may also select each external display for which brightness coordination is to be enabled using, for example, menu 780 of FIG. 7B. When brightness coordination module 230 determines that brightness coordination is disabled, method 500 may skip to block 545, where method 500 may stop. Otherwise, if brightness coordination is enabled, method 500 may proceed to block 520.

In block 520, brightness coordination module 230 may begin the brightness coordination procedure for the next display device for which brightness coordination is enabled. Method 500 may then proceed to block 525, where brightness coordination module 230 may transmit a brightness coordination message 240 to the display device if the display is an external display 250. This message 240 may instruct the display to set its current brightness level to the user-specified setting and may include a brightness setting as a level or percentage (e.g., 0 to 100) or a luminance level. When the display is an integrated display 216, brightness coordination module 230 may set the brightness setting of the integrated display 216 by, for example, transmitting an instruction to video interface 214.

After instructing the display to set its brightness level, method 500 may proceed to block 530, where brightness coordination module 230 may trigger an update of the power consumption level of the display device, as this level may change based on the new brightness setting. For example, brightness coordination module 230 may trigger the power consumption determination procedure described above in connection with FIG. 4.

After update of the power consumption level, method 500 may proceed to block 535, where brightness coordination module 230 may determine whether there are additional displays for which brightness coordination is enabled. If so, method 500 may return to block 520, where brightness coordination module 230 may coordinate the brightness level of the next display. When brightness coordination module 230 has coordinated the brightness of all displays for which coordination is enabled, method 500 may proceed to block 540, where brightness coordination module 230 may trigger power consumption reporting module 228 for a refresh of the displayed power consumption level of each display. Finally, method 500 may proceed to block 545, where method 500 may stop.

FIG. 6 is a flowchart of an example method 600 for controlling power states of a plurality of display devices of a computing device 200. Although execution of method 600 is described below with reference to computing device 200 and, more specifically, power state module 232, other suitable components for execution of method 600 will be apparent to those of skill in the art. Method 600 may be implemented in the form of executable instructions stored on a machine-readable storage medium and/or in the form of electronic circuitry.

Method 600 may start in block 605 and proceed to block 610, where power state module 232 may receive an enable indication from a user for a particular external display device 250. For example, the user may select or deselect a checkbox or similar interface element to indicate that he or she wishes to enable or disable a particular display 250. An example interface including elements 725 for enabling or disabling each external display 250 is described below in connection with FIG. 7A.

After receipt of an enable indication, method 600 may proceed to block 615, where power state module 232 may determine whether the received indication is a positive indication or a negative indication. If the received indication is positive, method 600 may proceed to block 620, where power state module 232 may transmit a power state message 242 instructing the display 250 to enter a power on state. Method 600 may then proceed to block 625, where power state module 232 may trigger a procedure for determining and displaying a brightness setting and/or power consumption level of the display 250, such as method 400 of FIG. 4. Method 600 may then proceed to block 640, where method 600 may stop.

Alternatively, when power state module 232 determines in block 615 that the enable indication is negative, method 600 may proceed to block 630, where power state module 232 may transmit a power state message 242 instructing the display 250 to enter a sleep or power off state. Method 600 may then proceed to block 635, where power state module 232 may trigger a procedure for determining the power consumption level of the display 250 in the sleep or power off state, such as method 400 of FIG. 4. Method 600 may then proceed to block 640, where method 600 may stop.

FIG. 7A is a block diagram of an example user interface 700 for displaying a level of power consumption 735 and controlling a power state of a plurality of display devices 720 of a computing device 100, 200. Example user interface 700 may be displayed, for example, as a window 710 in a power management application.

As illustrated, interface 700 may display a name and/or image for each of a plurality of display devices 720. Thus, in the depicted example, computing device 100, 200 currently has three displays 720 available: an integrated display; a 21″ 16:9 display; and a 15″ 4:3 display.

Interface 700 may also include a selectable enable element 725 for each external display device. Thus, as illustrated, interface 700 includes a checkbox for both the 21″ and the 15″ display. The 21″ display is currently enabled, while the 15″ display is currently disabled. By toggling either element 725, the user may trigger, for example, the power state management procedure described above in connection with FIG. 6.

Interface 700 may also display a brightness level 730 and current level of power consumption 735 determined based on the brightness or power state of the display 720. Thus, the integrated display is currently set to 60% brightness and is consuming 4 watts of power. The 21″ display is currently set to 40% brightness and is consuming 25 watts of power. Finally, the 15″ display is in a sleep state and is therefore consuming only 0.1 watts of power.

FIG. 7B is a block diagram of an example user interface 750 for coordinating brightness settings of a plurality of display devices of a computing device 100, 200. As with interface 700, example user interface 750 may be displayed, for example, as a window 760 in a power management application.

As illustrated, interface 750 may include a selectable element 765 for enabling the user to link the brightness of external displays to an operating system brightness control. In addition, interface 750 may include a selectable element 770 for enabling the user to coordinate brightness of each external display selected in menu 780, which may be displayed upon selection of button 775. Finally, interface 750 may include a slider 785 for controlling the brightness of the integrated display and any external displays for which brightness coordination is enabled.

Thus, as depicted, the user has currently enabled both selectable elements 765, 770 and has indicated that he or she wishes to coordinate the brightness of the 21″ 16:9 external display, identified by serial number 987654321. As a result, a change of brightness using either the OS brightness control or slider 785 will change the brightness of both the integrated display and, through the use of brightness coordination messages, the 21″ 16:9 display.

According to the foregoing, example embodiments disclosed herein determine a level of power consumption utilizing an operating parameter and power consumption data. In addition, example embodiments coordinate a brightness level of a plurality of displays and allow for user control of the power state of each display. In this manner, a user may reliably monitor and control a level of power consumption of all displays available to his or her computing device.

We claim:

1. A computing device comprising:
a video interface for communication with an external display device; and
a display management module comprising:
a parameter reading module to receive a current operating parameter of the external display device,
a power consumption reading module to receive power consumption data describing a level of power consumption of the external display device based on the operating parameter, and
a power determination module to determine a level of power consumption of the external display device based on application of the current operating parameter to the power consumption data.

2. The computing device of claim 1, wherein the parameter reading module:
receives the current operating parameter from the external display device via the video interface, or
receives the current operating parameter from a user of the computing device.

3. The computing device of claim 1, wherein the power consumption reading module:
receives the power consumption data from the external display device via the video interface,
receives the power consumption data from a user of the computing device, or
retrieves the power consumption data from a storage location accessible to the computing device.

4. The computing device of claim 1, wherein:
the current operating parameter includes a brightness setting of the external display device, and
the power consumption data provides a predetermined level of power consumption for each of a plurality of brightness settings.

5. The computing device of claim 4, wherein the power determination module determines the level of power consumption corresponding to the brightness setting of the external display device based on interpolation using at least two predetermined levels of power consumption.

6. The computing device of claim 4, further comprising:
a power consumption reporting module to display the brightness setting of the external display device and the determined level of power consumption.

7. The computing device of claim 1, wherein:
the computing device is connected to a plurality of display devices, including the external display device, and
the display management module further comprises a brightness coordination module to:
determine a brightness level specified by a user,
transmit a brightness coordination message to each external display device, the brightness coordination message instructing each external display device to set a brightness setting to the brightness level specified by the user, and
when the plurality of display devices includes an integrated display device, set a brightness setting of the integrated display device to the brightness level specified by the user.

8. The computing device of claim 1, wherein the display management module further comprises a power state module to:
receive an enable indication from a user via a displayed user interface that presents a selectable element for each of a plurality of external display devices, the enable indication specifying whether a particular external display device is to be enabled, and
transmit a power state control message to the particular external display device based on receipt of the respective enable indication, wherein the power state control message:
instructs the particular external display device to power on when the enable indication is positive, and
instructs the particular external display device to enter one of a sleep state and a power off state when the enable indication is negative.

9. A machine-readable storage medium encoded with instructions executable by a processor of a computing device, the machine-readable storage medium comprising:
instructions for receiving a respective operating parameter for each of a plurality of display devices, the plurality of display devices including an integrated display device and at least one external display device;
instructions for determining a respective level of power consumption of each display device of the plurality of display devices using the respective operating parameter; and
instructions for outputting each determined level of power consumption for each display device.

10. The machine-readable storage medium of claim 9, wherein the instructions for determining comprise, for a particular display device:
instructions for receiving power consumption data describing a predetermined level of power consumption of the particular display device for each of a plurality of operating parameter settings, and
instructions for determining the level of power consumption of the particular display device based on application of the operating parameter to the power consumption data.

11. The machine-readable storage medium of claim 9, further comprising:
instructions for coordinating a brightness setting of the plurality of display devices based on a brightness level specified by a user.

12. The machine-readable storage medium of claim 11, wherein the brightness level specified by the user is specified using one of:
a brightness control of an operating system of the computing device,
an on-screen display menu of an external display device, and
a user interface element outputted by the instructions for coordinating.

13. A method comprising:
determining, by a computing device, a current level of brightness of a plurality of display devices connected to the computing device;
determining a respective level of power consumption of each respective display device based on the current level of brightness of the respective display device; and
coordinating the level of brightness of each of the plurality of display devices based on a user-specified brightness setting.

14. The method of claim 13, wherein determining the respective level of power consumption comprises, for each display device:
receiving power consumption data including a predetermined level of power consumption for each of a plurality of brightness settings of the display device; and
interpolating the level of power consumption for the display device using the level of brightness and the power consumption data.

15. The method of claim 13, wherein the coordinating comprises:
transmitting a brightness coordination message to each external display device, the brightness coordination message instructing each external display device to set a brightness setting to the user-specified brightness setting; and
when the plurality of display devices includes an integrated display device, setting the level of brightness of the integrated display device to the user-specified brightness setting.
